(19) United States
(12) Patent Application Publication
(10) Pub. No.: US 2026/0254449 A1
(43) Pub. Date: Aug. 27, 2026

(54) Charging System and Dual Mode Power Conversion Circuit Thereof

(71) Applicant: Richtek Technology Corporation, Zhubei City (TW)

(72) Inventors: Ye-Sing Luo, Hsinchu (TW); Ching-Jan Chen, Taipei (TW); Jun-Hao Lai, New Taipei (TW)

(21) Appl. No.: 19/455,561

(22) Filed: Jan. 21, 2026

Related U.S. Application Data
(60) Provisional application No. 63/763,801, filed on Feb. 26, 2025.

(30) Foreign Application Priority Data
Jan. 2, 2026 (TW) 115100188

(51) Int. Cl. H03K 17/0814; H02J 7/90; H02J 7/96; H02M 1/088; H02M 3/07; H03K 7/08

(52) U.S. Cl. CPC H03K 17/08142; H02J 7/927; H02J 7/96; H02M 1/088; H02M 3/07; H03K 7/08; H03K 2217/0063; H03K 2217/0072

(57) ABSTRACT

A power conversion circuit for performing conversion between a first and a second power sources, includes: an N-level Pulse Width Modulation (PWM) power converter, configured to switch electrical connections of an inductor and a capacitor in an N-level PWM mode; and a switched-capacitor power converter, configured to switch electrical connections of the capacitor in a switched-capacitor conversion mode. During a mode transition between the N-level PWM mode and the switched-capacitor conversion mode, the power conversion circuit is configured to perform a soft-transition operation: during a soft-transition period, in a conduction state when a first switch is periodically switched, a voltage at a control terminal of the first switch is controlled to a bias voltage to limit a first switch current flowing through the first switch. The first switch corresponds to one of the switches in the N-level PWM power converter and the switched-capacitor power converter.

### CROSS REFERENCE

The present invention claims priority to provisional application 63/763,801 filed on February 26, 2025, and TW 115100188 filed on January 2, 2026.

### BACKGROUND OF THE INVENTION

### Field of Invention

The present invention relates to a dual-mode power conversion circuit. The present invention also relates to a charging system comprising the aforementioned dual-mode power conversion circuit.

### Description of Related Art

In a prior art multi-mode charging system, energy conversion is performed by driving an inductor in an N-level Pulse Width Modulation (PWM) mode. When the output voltage enters a mid-level voltage region, the system switches to a switched-capacitor conversion mode, which utilizes capacitive voltage division or a charge pump mechanism to achieve current multiplication and thereby accelerate the charging process. Such architectures are widely applied in buck or boost power converters.

However, in the aforementioned prior art, during mode transitions between the N-level PWM mode and the switched-capacitor conversion mode, significant differences exist between the inductor-based energy transfer mechanism of the PWM mode and the charge/discharge mechanism of the switched-capacitor mode. In addition, during mode transition, capacitor terminal voltages are often unbalanced, which can result in a large surge current when the switches are turned on. This surge current may cause the inductor and switching elements to experience excessive peak currents and may also induce oscillations, overshoots, or unintended transient conduction. Such phenomena adversely affect the reliability and efficiency of the entire converter, and thus constitute a technical bottleneck that needs to be addressed in hybrid architectures combining N-level PWM and switched-capacitor conversion modes.

### SUMMARY OF THE INVENTION

From one perspective, the present invention provides a power conversion circuit configured to convert a first power source to a second power source or convert the second power source to the first power source, comprising: an N-level Pulse Width Modulation (PWM) power converter, configured to switch electrical connections of an inductor and at least one capacitor in an N-level PWM mode to perform conversion between the first power source and the second power source; and a switched-capacitor power converter, configured to switch electrical connections of the at least one capacitor in a switched-capacitor conversion mode to perform conversion between the first power source and the second power source; wherein the N-level PWM power converter includes: a plurality of high-side switches serially coupled between the first power source and a switching node, wherein the plurality of high-side switches are sequentially coupled to at least one corresponding high-side intermediate node; and a plurality of low-side switches serially coupled between the switching node and a ground potential, wherein the plurality of low-side switches are sequentially coupled to at least one corresponding low-side intermediate node; wherein the plurality of high-side switches and the plurality of low-side switches are configured to periodically switch the electrical connections of the at least one capacitor in the N-level PWM mode, such that N-level voltages are generated at the switching node, enabling the inductor to perform conversion between the first power source and the second power source in an N-level pulse width modulation manner, where N is an integer equal to or greater than 3; wherein the switched-capacitor power converter includes: a plurality of shared switches, including a first portion of the plurality of high-side switches and a first portion of the plurality of low-side switches, wherein the shared switches are shared with the N-level PWM power converter; and a plurality of auxiliary switches, wherein the shared switches and the auxiliary switches are configured to periodically switch the electrical connections of the at least one capacitor in the switched-capacitor conversion mode to perform switched-capacitor power conversion between the first power source and the second power source; wherein in the switched-capacitor conversion mode, a second portion of the plurality of high-side switches and a second portion of the plurality of low-side switches are configured to remain non-conductive, such that a first terminal of the inductor is in a floating state; wherein in the N-level PWM mode, the plurality of auxiliary switches are configured to remain non-conductive, such that the at least one capacitor is not directly connected to the second power source; wherein during a mode transition between the N-level PWM mode and the switched-capacitor conversion mode, the power conversion circuit is configured to perform a soft-transition operation, in which, during a soft-transition period, when a first switch is in a conduction state while being periodically switched, a voltage at a control terminal of the first switch is controlled to a bias voltage to limit a first switch current flowing through the first switch; wherein the first switch corresponds to one of the plurality of high-side switches, the plurality of low-side switches or the plurality of auxiliary switches.

In one embodiment, after the soft-transition period ends, when the first switch is in a conduction state while being periodically switched, a voltage at a control terminal of the first switch is controlled to a driving voltage, wherein an absolute value of the driving voltage is greater than an absolute value of the bias voltage.

In one embodiment, the soft-transition period is positively correlated with a product of a capacitance of the at least one capacitor and an on-resistance of the first switch when conducting.

In one embodiment, during the soft-transition operation, when a voltage difference across the at least one capacitor falls within a target range, the soft-transition period is triggered to end, wherein the target range is related to a second voltage of the second power source.

In one embodiment, the power conversion circuit further comprises a control circuit configured to control the first switch, wherein the control circuit includes: a driving circuit configured to generate a first control signal according to a PWM signal, wherein the first control signal is configured, during a switching period other than the soft-transition period, to control the control terminal of the first switch such that the first switch is periodically switched according to a duty cycle of the PWM signal, wherein an amplitude of the first control signal corresponds to the driving voltage; and a current mirror circuit configured to generate a second control signal based on the PWM signal and a reference limit current, wherein the second control signal is configured, during the soft-transition period, to control the control terminal of the first switch so as to limit the first switch current, wherein an amplitude of the second control signal corresponds to the bias voltage; wherein the first switch current is related to the reference limit current.

In one embodiment, in the N-level PWM mode, a ratio between a first voltage of the first power source and a second voltage of the second power source corresponds to a duty cycle associated with the N-level voltages; and wherein in the switched-capacitor conversion mode, the ratio between the first voltage and the second voltage is M, and a first current of the first power source is constant, such that a second current of the second power source is constant and equal to M times the first current, where M is a real number greater than 1.

In one embodiment, the plurality of high-side switches include a first high-side switch and a second high-side switch serially coupled between the first power source and the switching node, and the first high-side switch and the second high-side switch are coupled to each other at a first high-side intermediate node; wherein the plurality of low-side switches include a first low-side switch and a second low-side switch serially coupled between the ground potential and the switching node, and the first low-side switch and the second low-side switch are coupled to each other at a first low-side intermediate node; wherein the first high-side switch and the first low-side switch correspond to the plurality of shared switches; wherein the plurality of auxiliary switches include an upper auxiliary switch and a lower auxiliary switch, the upper auxiliary switch being coupled between the second power source and the first high-side intermediate node, and the lower auxiliary switch being coupled between the second power source and the first low-side intermediate node; wherein the at least one capacitor includes a first capacitor, the first capacitor being coupled between the first high-side intermediate node and the first low-side intermediate node; and wherein the first terminal of the inductor is coupled to the switching node, and a second terminal of the inductor is coupled to the second power source.

In one embodiment, N is equal to 3, wherein the N-level PWM mode corresponds to a 3-level PWM mode which includes: a state A, in which the first high-side switch and the second low-side switch are conductive, and the second high-side switch and the first low-side switch are non-conductive, such that, in a steady state, a voltage at the switching node in the state A corresponds to one-half of the first voltage; a state B, in which the first low-side switch and the second low-side switch are conductive, and the first high-side switch and the second high-side switch are non-conductive, such that the voltage at the switching node in the state B corresponds to the ground potential; a state C, in which the second high-side switch and the first low-side switch are conductive, and the first high-side switch and the second low-side switch are non-conductive, such that, in a steady state, the voltage at the switching node in the state C corresponds to one-half of the first voltage; and a state D, in which the first high-side switch and the second high-side switch are conductive, and the first low-side switch and the second low-side switch are non-conductive, such that the voltage at the switching node in the state D corresponds to the first voltage; wherein in the 3-level PWM mode, the power conversion circuit periodically switches between combinations of the states A, B, C, and D within a switching cycle, such that the voltage at the switching node alternates between the first voltage and one-half of the first voltage, or alternates between one-half of the first voltage and the ground potential; wherein in the 3-level PWM mode, the upper auxiliary switch and the lower auxiliary switch remain non-conductive, such that the first capacitor is not directly connected to the second power source.

In one embodiment, M is equal to 2, wherein the switched-capacitor conversion mode includes: a state E, in which the first high-side switch and the lower auxiliary switch are conductive, and the upper auxiliary switch and the first low-side switch are non-conductive; and a state F, in which the upper auxiliary switch and the first low-side switch are conductive, and the first high-side switch and the lower auxiliary switch are non-conductive; wherein in the switched-capacitor conversion mode, the power conversion circuit is configured to periodically switch between the state E and the state F within a switching cycle, such that: a first terminal of the first capacitor is periodically switched between the first voltage and the second voltage; and a second terminal of the first capacitor is periodically switched between the second voltage and the ground potential correspondingly; wherein in the switched-capacitor conversion mode, the second high-side switch and the second low-side switch remain non-conductive, such that a first terminal of the inductor is in a floating state.

From another perspective, the present invention provides a charging system, comprising: a power supplying unit configured to generate a direct current (DC) power source according to an input power source, wherein, in a switched-capacitor conversion mode, a direct current included in the direct current power source is constant; and a charging circuit, connected to the power supplying unit with a detachable manner, configured to convert the DC power source into a charging power source to charge a battery, wherein the DC power source and the charging power source respectively correspond to one and the other of a first power source and a second power source, wherein the charging circuit includes: an N-level Pulse Width Modulation (PWM) power converter, configured to switch electrical connections of an inductor and at least one capacitor in an N-level PWM mode to perform conversion between the first power source and the second power source; and a switched-capacitor power converter, configured to switch electrical connections of the at least one capacitor in a switched-capacitor conversion mode to perform conversion between the first power source and the second power source; wherein the N-level PWM power converter includes: a plurality of high-side switches serially coupled between the first power source and a switching node, wherein the plurality of high-side switches are sequentially coupled to at least one corresponding high-side intermediate node; and a plurality of low-side switches serially coupled between the switching node and a ground potential, wherein the plurality of low-side switches are sequentially coupled to at least one corresponding low-side intermediate node; wherein the plurality of high-side switches and the plurality of low-side switches are configured to periodically switch the electrical connections of the at least one capacitor in the N-level PWM mode, such that N-level voltages are generated at the switching node, enabling the inductor to perform conversion between the first power source and the second power source in an N-level pulse width modulation manner, where N is an integer equal to or greater than 3; wherein the switched-capacitor power converter includes: a plurality of shared switches, including a first portion of the plurality of high-side switches and a first portion of the plurality of low-side switches, wherein the shared switches are shared with the N-level PWM power converter; and a plurality of auxiliary switches, wherein the shared switches and the auxiliary switches are configured to periodically switch the electrical connections of the at least one capacitor in the switched-capacitor conversion mode to perform switched-capacitor power conversion between the first power source and the second power source; wherein in the switched-capacitor conversion mode, a second portion of the plurality of high-side switches and a second portion of the plurality of low-side switches are configured to remain non-conductive, such that a first terminal of the inductor is in a floating state; wherein in the N-level PWM mode, the plurality of auxiliary switches are configured to remain non-conductive, such that the at least one capacitor is not directly connected to the second power source; wherein during a mode transition between the N-level PWM mode and the switched-capacitor conversion mode, the power conversion circuit is configured to perform a soft-transition operation, in which, during a soft-transition period, when a first switch is in a conduction state while being periodically switched, a voltage at a control terminal of the first switch is controlled to a bias voltage to limit a first switch current flowing through the first switch; wherein the first switch corresponds to one of the plurality of high-side switches, the plurality of low-side switches or the plurality of auxiliary switches.

In one embodiment, the charging circuit switches between the N-level PWM mode and the switched-capacitor conversion mode based on a feedback signal, wherein the feedback signal is related to a charging voltage or a charging current of the charging power; wherein when a battery voltage of the battery is lower than a first predetermined voltage, the charging circuit operates in the N-level PWM mode to generate the charging current at a first level through pulse width modulation control based on the feedback signal to charge the battery; wherein when the battery voltage is higher than the first predetermined voltage and lower than a second predetermined voltage, the charging circuit operates in the switched-capacitor conversion mode to generate the charging current at a second level to charge the battery, wherein the second level has a current multiplication ratio with respect to the direct current, wherein the first predetermined voltage is lower than the second predetermined voltage; wherein when the battery voltage is higher than the second predetermined voltage, the charging circuit operates in the N-level PWM mode to generate the charging voltage at a predetermined level based on the feedback signal to charge the battery.

During a mode transition between the N-level PWM mode and the capacitor conversion mode, the present invention utilizes a soft-transition operation to suppress surge current, thereby enhancing circuit stability and ensuring device safety. The soft-transition operation may adaptively determine and control the soft-transition period based on a capacitance or a voltage difference across a capacitor in the power conversion circuit.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a block diagram of one embodiment of the power conversion circuit of the present invention.

FIG. 1B shows a block diagram of one embodiment of the charging system of the present invention.

FIG. 2 shows a schematic diagram of one specific embodiment of the power conversion circuit of the present invention.

FIG. 3A shows a schematic diagram of one specific embodiment of the charging system of the present invention.

FIG. 3B shows a schematic diagram of another specific embodiment of the charging system of the present invention.

FIG. 3C shows a schematic diagram of one specific embodiment of a power supplying system of the present invention.

FIG. 4 shows an operational waveform diagram of one embodiment of the power conversion circuit corresponding to FIG. 3A or FIG. 3B.

FIG. 5 shows a schematic diagram of one specific embodiment of a control circuit in the power conversion circuit of the present invention.

FIG. 6A shows a schematic diagram of one specific embodiment of a logic circuit in the control circuit of the present invention.

FIG. 6B shows a schematic diagram of another specific embodiment of a logic circuit in the control circuit of the present invention.

FIG. 7 shows an operational waveform diagram of one embodiment of the power conversion circuit of the present invention.

FIG. 8A shows an operational waveform diagram of one embodiment corresponding to FIG. 6A of the present invention.

FIG. 8B shows an operational waveform diagram of one embodiment corresponding to FIG. 6B of the present invention.

FIG. 9 shows a schematic diagram of one specific embodiment of a delay signal generation circuit in the power conversion circuit of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

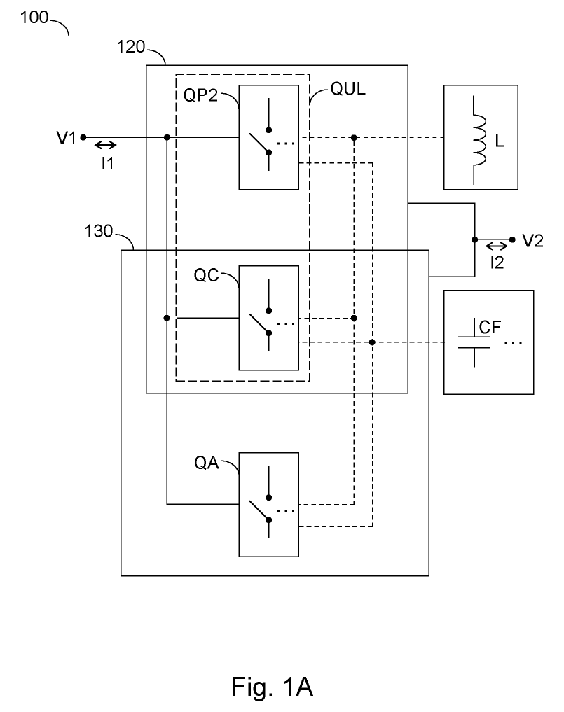

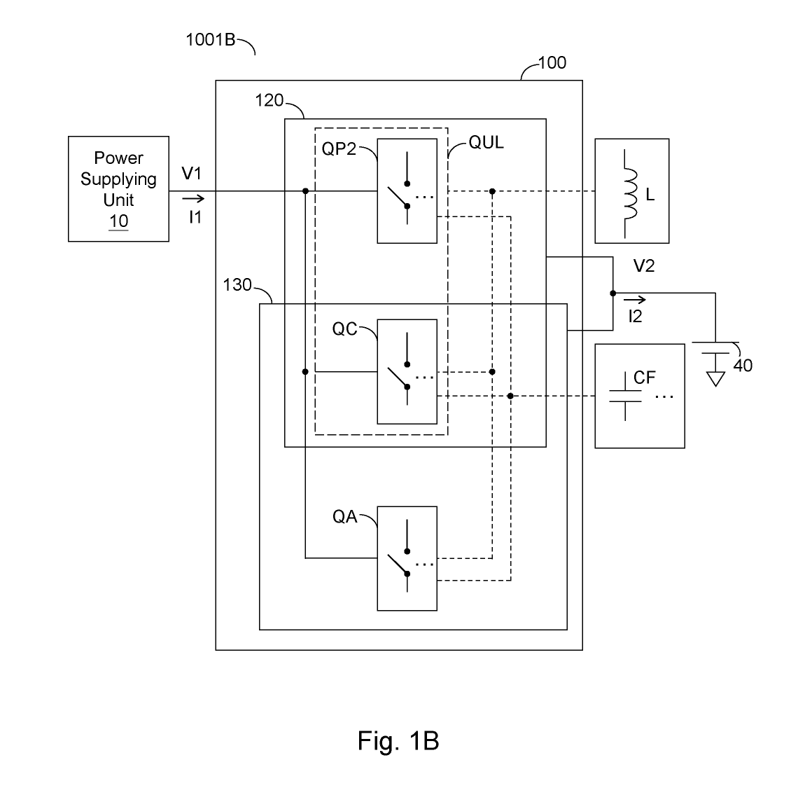

FIG. 1A shows a block diagram of one embodiment of the power conversion circuit of the present invention. As shown in FIG. 1A, the power conversion circuit 100 is configured to convert a first power source into a second power source or to convert the second power source into the first power source. The power conversion circuit 100 includes an N-level Pulse Width Modulation (PWM) power converter 120 and a switched-capacitor power converter 130.

The N-level PWM power converter 120 is configured to switch electrical connections of an inductor L and at least one capacitor (e.g., CF) in an N-level PWM mode to perform power conversion between the first power source and the second power source. The switched-capacitor power converter 130 is configured to switch the electrical connections of the at least one capacitor in a switched-capacitor conversion mode to perform power conversion between the first and second power sources.

In one embodiment, the N-level PWM power converter 120 includes a plurality of PWM switches QUL, which include a plurality of high-side switches and a plurality of low-side switches. The plurality of PWM switches QUL periodically switch the electrical connections of the at least one capacitor in the N-level PWM mode, such that the inductor L performs power conversion between the first and second power sources in an N-level PWM manner, where N is an integer greater than or equal to 3.

In one embodiment, the switched-capacitor power converter 130 includes a plurality of shared switches QC and a plurality of auxiliary switches QA. The shared switches QC include a first portion of the high-side switches and a first portion of the low-side switches, and are shared with the N-level PWM power converter 120. In the switched-capacitor conversion mode, the shared switches QC and the auxiliary switches QA are configured to periodically switch the electrical connections of the at least one capacitor to perform switched-capacitor power conversion between the first and second power sources.

In one embodiment, a second portion of the PWM switches QUL includes second high-side and low-side switches, referred to as QP2. The plurality of PWM switches QUL thus include the shared switches QC and the second portion switches QP2, i.e., the PWM switches QUL include the first and second portions of the high-side switches, and the first and second portions of the low-side switches.

In one embodiment, during the switched-capacitor conversion mode, the second portion switches QP2 remain non-conductive, such that a first terminal of the inductor L is in a floating state. During the N-level PWM mode, the auxiliary switches QA remain non-conductive, such that the at least one capacitor is not directly connected to the second power source.

In one embodiment, in the switched-capacitor conversion mode, the ratio between a first voltage V1 of the first power source and a second voltage V2 of the second power source is defined as M. In one embodiment, by configuring the capacitors and switches, M is a real number greater than 1. In another embodiment, M is an integer greater than 1.

FIG. 1B shows a schematic diagram of one specific embodiment of the charging system 1001B of the present invention. In one embodiment, a power supplying unit 10 is configured to generate the first power source, and the power conversion circuit 100 is configured to convert the first power source into the second power source. In one embodiment, the power supplying unit 10 controls a first current I1 of the first power source to be constant (e.g., set to a predetermined level). In the switched-capacitor conversion mode, a second current I2 of the second power source generated by the power conversion circuit 100 is also constant and is equal to M times the first current I1.

In one embodiment, in the N-level PWM mode, the ratio between a first voltage V1 of the first power source and a second voltage V2 of the second power source is associated with a duty cycle corresponding to the N-level voltages. In one embodiment, the N-level voltages include, for example, the first voltage V1, the ground potential, and (N−2) voltages between the first voltage V1 and the ground potential. In one embodiment, M is an integer and is equal to (N−1).

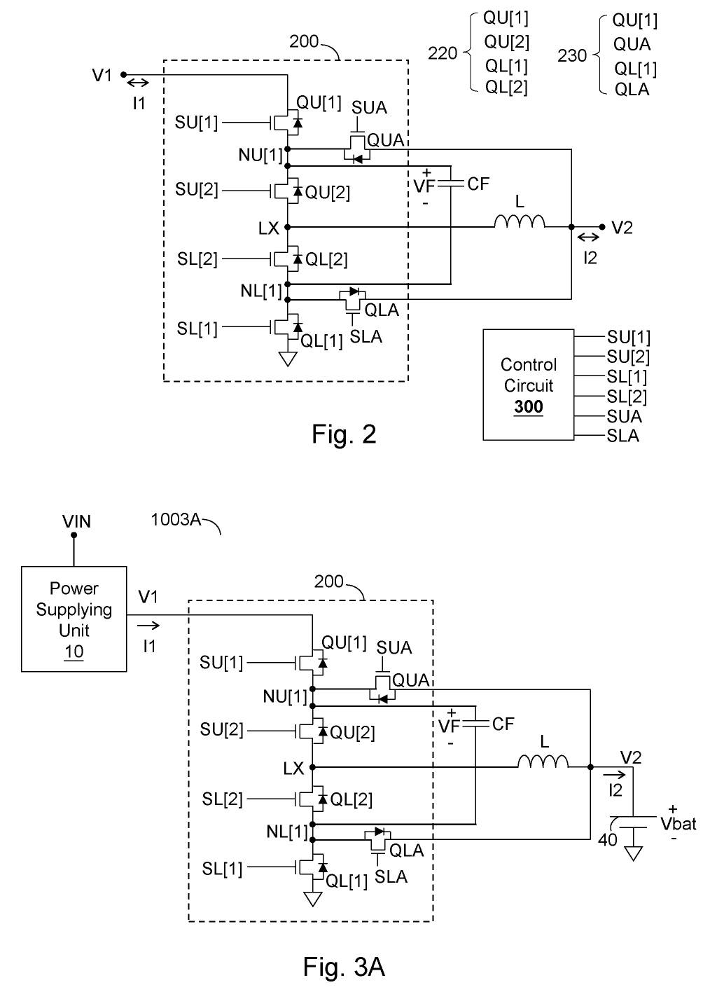

FIG. 2 shows a schematic diagram of one specific embodiment of the power conversion circuit 200 of the present invention. The power conversion circuit 200 is configured to convert the first power source (corresponding to a first voltage V1 and a first current I1) to the second power source, or convert the second power source (corresponding to a second voltage V2 and a second current I2) to the first power source. The power conversion circuit 200 includes a 3-level PWM power converter 220 and a switched-capacitor power converter 230. In this embodiment, N is equal to 3. In other words, the aforementioned N-level PWM power converter corresponds to the 3-level PWM power converter 220 in this embodiment, and the aforementioned N-level PWM mode corresponds to the 3-level PWM mode in this embodiment.

In one embodiment, as shown in FIG. 2, the at least one capacitor includes a capacitor CF. In one embodiment, the 3-level PWM power converter 220 is configured to periodically switch the electrical connection of the capacitor CF in a 3-level PWM mode, such that 3-level voltages are generated at the switching node LX, thereby enabling an inductor L to perform power conversion between the first and second power sources in a 3-level PWM manner. The switched-capacitor power converter 230 is configured to switch the electrical connection of the capacitor CF in the switched-capacitor conversion mode to perform power conversion between the first and second power sources.

In this embodiment, the plurality of high-side switches include a first high-side switch QU[1] and a second high-side switch QU[2], which are serially connected between the first power source and a switching node LX. The first high-side switch QU[1] and the second high-side switch QU[2] are commonly coupled to a high-side intermediate node NU[1]. The plurality of low-side switches include a first low-side switch QL[1] and a second low-side switch QL[2], which are serially connected between the ground potential and the switching node LX. The first low-side switch QL[1] and the second low-side switch QL[2] are commonly coupled to a low-side intermediate node NL[1]. In this embodiment, the inductor L is coupled between the switching node LX and the second power source.

On the other hand, in the switched-capacitor power converter 230, the aforementioned shared switches QC include the first high-side switch QU[1] and the first low-side switch QL[1], and the aforementioned auxiliary switches QA include an upper auxiliary switch QUA and a lower auxiliary switch QLA. In other words, the 3-level PWM power converter 220 and the switched-capacitor power converter 230 share the first high-side switch QU[1] and the first low-side switch QL[1]. In this embodiment, the upper auxiliary switch QUA is coupled between the second power source and the high-side intermediate node NU[1], and the lower auxiliary switch QLA is coupled between the second power source and the low-side intermediate node NL[1]. The capacitor CF is coupled between the high-side intermediate node NU[1] and the low-side intermediate node NL[1]. In this embodiment, a control circuit 300 is configured to generate control signals SU[1], SU[2], SL[1], SL[2], SUA and SLA, to respectively control the corresponding high-side switches, low-side switches, and the upper and lower auxiliary switches.

It should be noted that in the embodiment of the N-level PWM power converter 120 shown in FIG. 1A, the plurality of high-side switches are sequentially coupled to at least one corresponding high-side intermediate node, and the plurality of low-side switches are sequentially coupled to at least one corresponding low-side intermediate node. Those skilled in the art may infer this from the explanation in FIG. 2.

Still referring to FIG. 2, in the 3-level PWM mode, the power conversion circuit 200 is controlled by control signals SU[1], SU[2], SL[1], and SL[2] to perform periodical switching based on a switching cycle. The 3-level PWM mode includes the following states: In state A, the first high-side switch QU[1] and the second low-side switch QL[2] are turned on (i.e., conductive), while the second high-side switch QU[2] and the first low-side switch QL[1] are turned off (i.e., non-conductive). The voltage at the switching node LX corresponds to one-half of the first voltage V1 during a steady state. In state B, the first low-side switch QL[1] and the second low-side switch QL[2] are turned on, while the first high-side switch QU[1] and the second high-side switch QU[2] are turned off. The voltage at the switching node LX corresponds to the ground potential. In state C, the second high-side switch QU[2] and the first low-side switch QL[1] are turned on, while the first high-side switch QU[1] and the second low-side switch QL[2] are turned off. The voltage at the switching node LX also corresponds to one-half of the first voltage V1 during a steady state. In state D, the first high-side switch QU[1] and the second high-side switch QU[2] are turned on, while the first low-side switch QL[1] and the second low-side switch QL[2] are turned off. The voltage at the switching node LX corresponds to the first voltage V1. By switching between states in a combination of the above states A, B, C, and D, the voltage at the switching node LX can periodically alternate between different voltage levels. For example: In a first operation mode, the power conversion circuit cycles through state D → state A → state D → state C…, such that the voltage at LX alternates between the first voltage V1 and one-half of V1. In a second operation mode, the power conversion circuit cycles through state A → state B → state C → state B…, such that the voltage at LX alternates between one-half of V1 and the ground potential. By employing the above first and/or second operation modes, a 3-level PWM power conversion control method is achieved.

It should be noted that in the 3-level PWM mode, after switching of the power conversion circuit has reached a steady state, the cross-voltage VF of the capacitor CF is one-half of the first voltage V1 and the ratio between the first voltage V1 of the first power source and the second voltage V2 of the second power source corresponds to the duty cycle associated with the aforementioned 3-level voltages. In the aforementioned first operation mode, V2 is between V1 and (1/2) × V1; whereas in the second operation mode, V2 is between (1/2) × V1 and 0. Moreover, the switching sequence of the states within a switching cycle can be arranged according to actual application requirements. The described sequence of state transitions within one switching cycle is not intended to limit the broadest scope of the present invention.

It should also be noted that in the 3-level PWM mode, the upper auxiliary switch QUA and the lower auxiliary switch QLA remain non-conductive, such that the capacitor CF is not directly connected to the second power source.

Still referring to FIG. 2, in the switched-capacitor conversion mode, the power conversion circuit 200 is controlled by control signals SU[1], SUA, SLA, and SL[1] to perform periodical switching based on a switching cycle. The switched-capacitor conversion mode includes the following two states: In state E, the first high-side switch QU[1] and the lower auxiliary switch QLA are turned on, while the upper auxiliary switch QUA and the first low-side switch QL[1] are turned off. In this state, the first terminal of the capacitor CF is connected to the first voltage V1, and the second terminal is connected to the second voltage V2. In state F, the upper auxiliary switch QUA and the first low-side switch QL[1] are turned on, while the first high-side switch QU[1] and the lower auxiliary switch QLA are turned off. The first terminal of the capacitor CF is connected to the second voltage V2, and the second terminal is connected to the ground potential. By alternately switching between state E and state F, the voltages on the two terminals of the capacitor CF also alternate periodically. Specifically, the first terminal of the capacitor alternates between the first voltage V1 and the second voltage V2, and the second terminal alternates between the second voltage V2 and the ground potential correspondingly. As a result, the voltage ratio between V1 and V2 is 2 (i.e., M = 2 in this embodiment), and the ratio between the second current I2 and the first current I1 is also 2. The switching cycle of the switched-capacitor conversion mode may be the same as or different from that of the 3-level PWM mode.

It should be noted that in the switched-capacitor conversion mode, the second high-side switch QU[2] and the second low-side switch QL[2] remain non-conductive, thereby making the switching node LX an open circuit; that is, a first terminal of the inductor L coupled to the switching node LX is in a floating state.

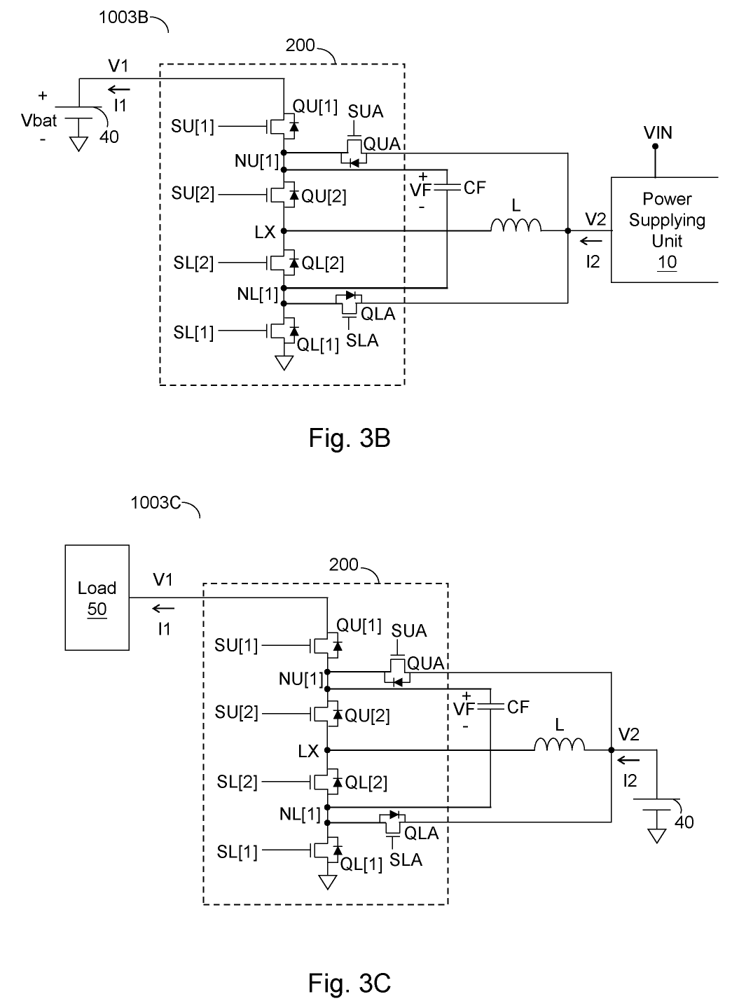

FIG. 3A shows a schematic diagram of one specific embodiment of the charging system 1003A of the present invention. The charging system 1003A includes a power supplying unit 10 and a power conversion circuit 200. The power supplying unit 10 is configured to generate a first power source based on an input power source (e.g., VIN). In one embodiment, the first power source is a direct current (DC) power source.

In one embodiment, the power supplying unit 10 may be an AC-DC conversion circuit, such as a mobile adapter. In this case, the input power source VIN is an alternating current (AC) power source. In another embodiment, the power supplying unit 10 may be a DC-DC conversion circuit, such as a power bank. In this case, the input power source VIN may be a direct current (DC) power source provided by another battery. In one embodiment, the power supplying unit 10 may comply with the USB PD (Universal Serial Bus Power Delivery) specification and may output the first power source in the form of an adjustable constant voltage or constant current according to application requirements.

The power conversion circuit 200 is connected to the power supplying unit 10 with a detachable manner, for example via a connector and cable. The power conversion circuit 200 is configured to convert the first power source to generate a charging power source for charging a battery 40. In this embodiment, the charging power source corresponds to the second power source as shown in the FIGURE(i.e., the second voltage V2 corresponds to the charging voltage, and the second current I2 corresponds to the charging current). In other words, in this embodiment, the power conversion circuit 200 operates in a buck mode under the 3-level PWM mode, or operates in a capacitive voltage division mode (corresponding to capacitive current multiplication) under the switched-capacitor conversion mode. In one embodiment, under the switched-capacitor conversion mode, the first current I1 generated by the power supplying unit 10 is constant, such that the second current I2 is also constant and is twice the first current I1 (i.e., current multiplication).

FIG. 3B shows a schematic diagram of another embodiment of the charging system 1003B of the present invention. The charging system 1003B is similar to the charging system 1003A, with the main difference being that in the charging system 1003B, the second power source corresponds to a direct current (DC) power source, and the first power source corresponds to the charging power source. In other words, in this embodiment, the power conversion circuit 200 operates in a boost mode under the 3-level PWM mode, or operates in a charge pump mode (corresponding to current down-conversion) under the switched-capacitor conversion mode to generate the first power source and charge the battery 40. In one embodiment, the second current I2 generated by the power supplying unit 10 is constant (e.g., set to a predetermined level), such that the first current I1 is also constant and is half the second current I2 (i.e., current down-conversion). In one embodiment, the second voltage V2 generated by the power supplying unit 10 is constant, such that the first voltage V1 is also constant and is twice the second voltage V2 (i.e., voltage boosting).

FIG. 3C illustrates a schematic diagram of a power supply system according to one embodiment of the present invention (power supply system 1003C). The power supply system 1003C is similar to the charging system 1003B. In this embodiment, the battery 40 provides the second power source, i.e., the battery voltage corresponds to the second voltage V2, and the battery current corresponds to the second current I2. The power conversion circuit 200 operates in a 3-level PWM mode to perform a boost operation, or operates in a switched-capacitor conversion mode to perform a charge pump operation (corresponding to current down-conversion), so as to convert the second power source provided by the battery 40 into a first power source for supplying power to a load 50. The power supply system 1003C, for example, corresponds to a battery-powered system complying with the USB OTG (USB On-The-Go) specification. In one embodiment, the second voltage V2 provided by the battery 40 is constant, such that the first voltage V1 is also constant and is twice the second voltage V2 (i.e., voltage boost).

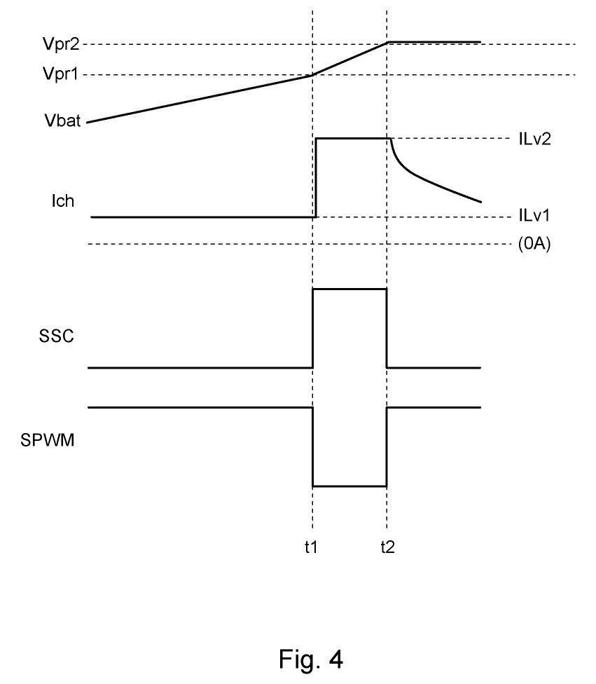

Please refer to FIGS. 3A, 3B and 4. FIG. 4 illustrates the waveform diagram of the operation of one embodiment of the power conversion circuit corresponding to FIG. 3A or FIG. 3B. In one embodiment, the power conversion circuit 200 in FIGS. 3A and 3B corresponds respectively to the charging circuits of the charging systems 1003A and 1003B. In one embodiment, the charging circuit (i.e., power conversion circuit 200, same hereinafter) switches between the N-level PWM mode and the switched-capacitor conversion mode according to a feedback signal, wherein the feedback signal is related to the battery voltage Vbat or the charging current Ich of the battery 40. In the embodiment of FIG. 3A, the charging current Ich corresponds to the second current I2 of the second power source.

In one embodiment, as shown in FIG. 4, when the feedback signal indicates that the battery voltage Vbat is lower than a first predetermined voltage Vpr1 (e.g., before time t1), the charging circuit operates in the N-level PWM mode according to a modulation mode signal SPWM. A pulse width modulation control is performed based on a feedback current signal related to the feedback signal to generate a charging current Ich of a first level ILv1 for charging the battery 40. The feedback current signal is related to the charging current Ich. For example, the feedback current signal is generated by sensing the charging current Ich. In one embodiment, the feedback current signal is proportional to the charging current Ich. In the embodiment of FIG. 3A, the charging current Ich corresponds to the second current I2 of the second power source. In the embodiment of FIG. 3B, the charging current Ich corresponds to the first current I1 of the first power source.

In one embodiment, when the feedback signal indicates that the battery voltage Vbat is higher than the first predetermined voltage Vpr1 and lower than a second predetermined voltage Vpr2 (e.g., between time t1 and time t2), the charging circuit operates in the switched-capacitor conversion mode according to a switched-capacitor conversion mode signal SSC to charge the battery 40 with a charging current Ich of a second level ILv2. In the embodiment of FIG. 4, the second level ILv2 may be greater than the first level ILv1. In one embodiment, the first predetermined voltage Vpr1 is lower than the second predetermined voltage Vpr2. In the embodiment corresponding to FIG. 3A, the charging circuit performs a switched-capacitor power conversion in an open-loop manner under the switched-capacitor conversion mode, providing a current multiplication effect. Specifically, the second level ILv2 has a current multiplication ratio relative to the first current I1, such as a factor of 2.

In one embodiment, when the feedback signal indicates that the battery voltage Vbat is higher than the second predetermined voltage Vpr2 (e.g., after time t2), the charging circuit operates in the N-level PWM mode according to the modulation mode signal SPWM. A pulse width modulation control is then performed according to the feedback signal to generate a constant voltage (e.g., corresponding to charging voltage at a predetermined level) for charging the battery 40. In the embodiment of FIG. 3A, the constant voltage corresponds to the second voltage V2 of the second power source. In the embodiment of FIG. 3B, the constant voltage corresponds to the first voltage V1 of the first power source.

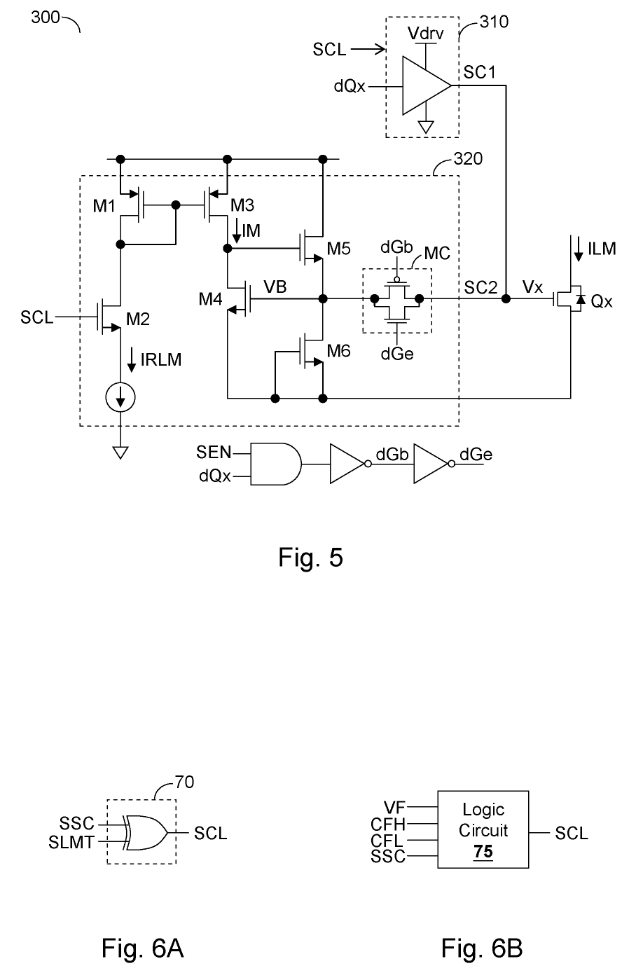

FIG. 5 illustrates a schematic diagram of a control circuit 300 in the power conversion circuit of the present invention. In one embodiment, the control circuit 300 includes a driving circuit 310 and a current mirror circuit 320 and is configured to control a first switch Qx.

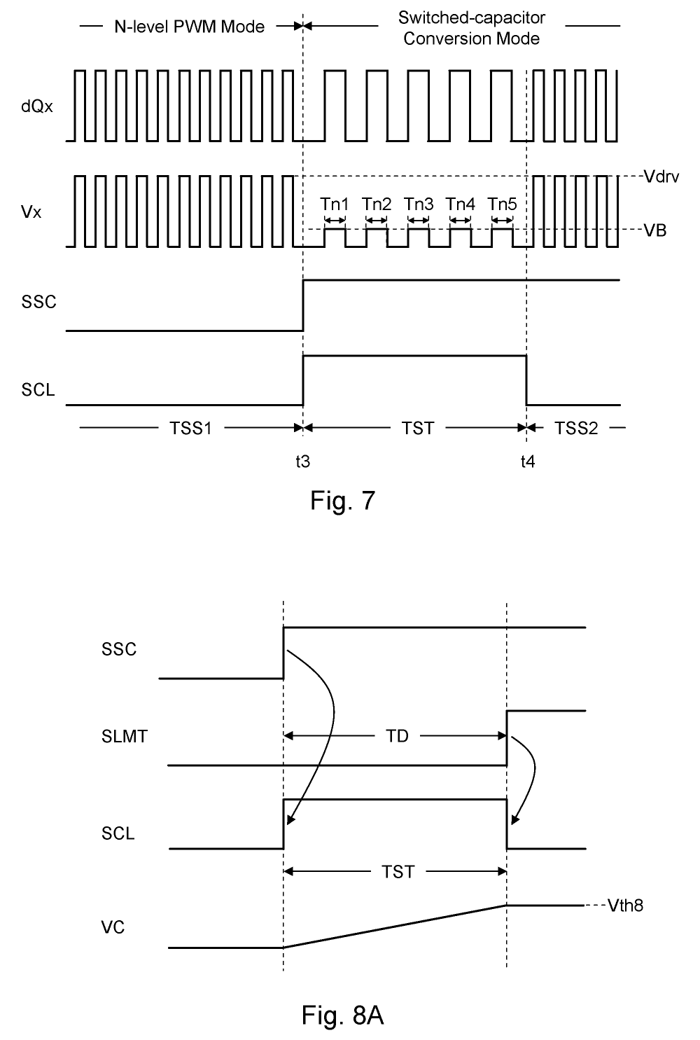

Please refer to FIGS. 5 and 7. FIG. 7 illustrates an operation waveform diagram of one embodiment of the power conversion circuit of the present invention. In one embodiment, during a mode transition between the N-level PWM mode and the switched-capacitor conversion mode, the power conversion circuit performs a soft-transition operation: during the soft-transition period TST, when the first switch Qx is in a conduction state while being periodically switched (e.g., the conduction times Tn1 to Tn5 in FIG. 7), the voltage Vx at the control terminal of the first switch Qx is continuously and analogically controlled to a bias voltage VB, so as to limit the first switch current flowing through Qx to a limit current ILM, thereby reducing the surge current during the mode transition. In one embodiment, the mode transition, for example, starts at time t3 in FIG. 7 and corresponds to transitioning from the N-level PWM mode to the switched-capacitor conversion mode. In other embodiments, the mode transition may also corresponds to transitioning from the switched-capacitor conversion mode to the N-level PWM mode.

In one embodiment, the first switch Qx corresponds to one or more of the plurality of PWM switches QUL (i.e., the plurality of upper-bridge and lower-bridge switches) and the auxiliary switches QA.

In one embodiment, the driving circuit 310 is configured to generate a first control signal SC1 according to the PWM signal dQx, wherein the amplitude of SC1 corresponds to the driving voltage Vdrv. The first control signal SC1 is configured to control the control terminal of the first switch Qx during a switching period other than the soft-transition period TST (e.g., switching period TSS1 before time t3 and switching period TSS2 after time t4 in FIG. 7), such that the first switch Qx periodically switches based on the duty cycle of the PWM signal dQx. During the conduction states of the periodic switching of dQx in the periods TSS1 and TSS2, the first control signal SC1 controls the voltage Vx at the control terminal of Qx to the driving voltage Vdrv.

In one embodiment, in the N-level PWM mode, the duty cycle is determined based on feedback control, and may range between 0% and 100%. In the switched-capacitor conversion mode, the duty cycle is, for example, 50%, or approximately 50% but slightly less due to the inclusion of dead time in the switching period.

In one specific embodiment, the current limit signal SCL is enabled in response to the capacitor mode signal SSC being enabled, thereby indicating that the control circuit 300 should perform a soft-transition operation. During the soft-transition period TST, the transistor M2 is turned on based on the current limit signal SCL, so that transistors M1 and M3 generate a mirrored current IM based on a reference limit current IRLM. Transistors M3 to M5 perform feedback control according to the mirrored current IM to determine a bias voltage VB. Control signals dGb and dGe are configured to control switch MC to generate a second control signal SC2.

In this embodiment, the enable signal SEN and the PWM signal dQx are processed through an AND gate and an inverter to generate the control signal dGb, and dGb is further inverted to generate control signal dGe. The enable signal SEN remains enabled when the power conversion circuit is activated. Specifically, when the PWM signal dQx is enabled, the switch MC is controlled to turn on; conversely, when dQx is disabled, the switch MC is turned off.

In this embodiment, when both the current limit signal SCL and the PWM signal dQx are enabled, the second control signal SC2 is configured to control the voltage Vx at the control terminal of the first switch Qx to the bias voltage VB, thereby limiting the current flowing through Qx to the limit current ILM. The amplitude of SC2 corresponds to the bias voltage VB. It should be noted that the absolute value of the driving voltage Vdrv is greater than that of the bias voltage VB.

In one embodiment, when the current limit signal SCL is enabled and the PWM signal dQx is disabled, the first control signal SC1 controls the voltage Vx at the control terminal of the first switch Qx such that the first switch Qx is controlled to be off. In one embodiment, the enable signal SEN remains enabled when the power conversion circuit is activated. In other embodiments, the enable signal SEN may correspond to the current limit signal SCL, such that when the current limit signal SCL is enabled and the PWM signal dQx is enabled, the switch MC is turned on to allow current limiting of the first switch Qx; otherwise, the switch MC is turned off. It should be noted that, in one embodiment, when the current limit signal SCL is disabled, the driving circuit 310 is configured to control switching of the first switch Qx according to the PWM signal dQx, with an amplitude corresponding to the driving voltage Vdrv. In another embodiment, when the current limit signal SCL is enabled (e.g., during the soft-transition period TST), the output of the driving circuit 310 is set to high impedance when the PWM signal dQx is enabled (e.g., during Tn1), such that the first switch Qx is controlled by SC2 to perform current limiting. When the PWM signal dQx is disabled (e.g., between Tn1 and Tn2), the driving circuit 310 outputs, for example, a low level to turn off the first switch Qx.

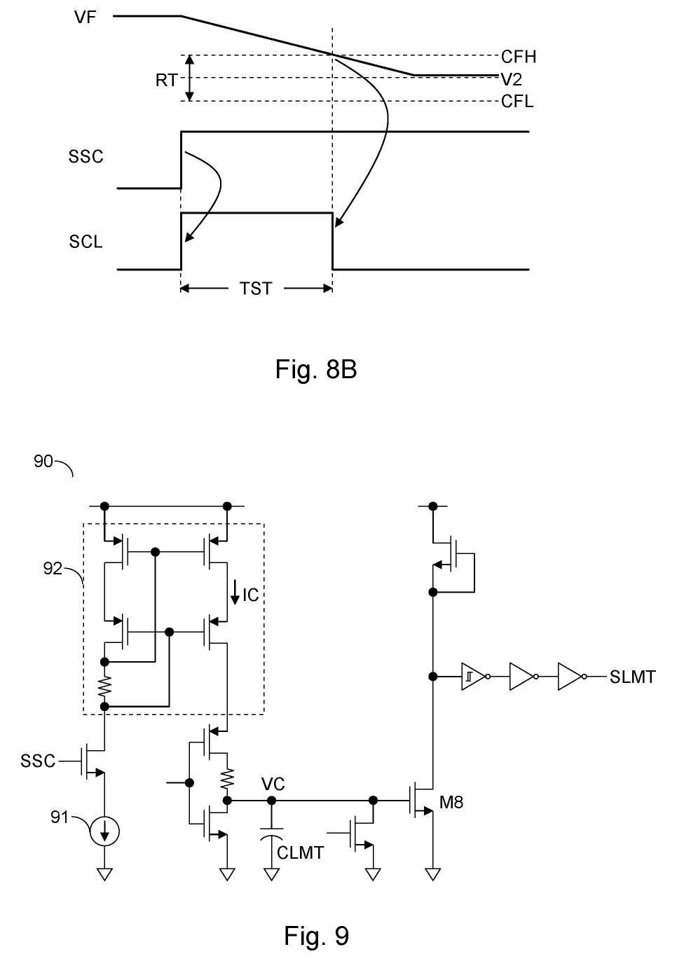

Please refer to FIGS. 6A and 8A. FIG. 6A illustrates a schematic diagram of one embodiment of a logic circuit within the control circuit of the present invention. FIG. 8A shows an operation waveform diagram corresponding to the embodiment in FIG. 6A. In one embodiment, the logic circuit 70 generates the current limit signal SCL based on the capacitor mode signal SSC and a delayed signal SLMT. The delayed signal SLMT is generated by delaying the capacitor mode signal SSC. In one embodiment, the delayed signal SLMT is enabled after a delay time TD once the SSC signal is enabled. In one specific embodiment, the logic circuit 70 may be implemented as an exclusive-OR gate. In this embodiment, the SCL signal is enabled based on the SSC signal being enabled, and disabled when the delayed signal SLMT becomes enabled.

In one embodiment, the delay time TD is determined according to the product of the capacitance of at least one capacitor (e.g., capacitor CF) and the on-resistance of the first switch Qx when turned on. Consequently, the soft-transition period TST is positively correlated with the product of the capacitance of at least one capacitor and the on-resistance of the first switch Qx.

Please refer to FIGS. 6B and 8B. FIG. 6B shows another embodiment of a logic circuit within the control circuit of the present invention. FIG. 8B illustrates an operation waveform diagram corresponding to the embodiment in FIG. 6B. In one embodiment, the logic circuit 75 generates the current limit signal SCL based on the voltage VF across the capacitor CF, a predetermined high threshold CFH, a predetermined low threshold CFL, and the capacitor mode signal SSC, and an enablement period of the current limit signal SCL is adaptively determined accordingly. In this embodiment, the current limit signal SCL is enabled when the capacitor mode signal SSC is enabled, and disabled when the capacitor voltage VF falls within a target range RT. In other words, when the capacitor voltage VF falls within the target range RT, the end of the soft-transition period TST is triggered.

In one embodiment, the target range RT is related to the second voltage V2 of the second power source. In this embodiment, the target range RT refers to a voltage range between a predetermined high threshold CFH and a predetermined low threshold CFL. In the embodiment corresponding to FIG. 3A, during switched-capacitor conversion mode, the steady-state voltage across capacitor CF (VF) tends to approach the second voltage V2. In this case, the high threshold CFH may be set higher than V2, and the low threshold CFL may be set lower than V2. In one embodiment, CFH and CFL may, for example, be respectively set to V2 ± ΔV, where ΔV corresponds to one half of the aforementioned target range RT.

FIG. 9 illustrates a schematic diagram of one specific embodiment of a delay signal generation circuit within the power conversion circuit of the present invention. In one embodiment, the delay signal generation circuit 90 generates the delayed signal SLMT based on the capacitor mode signal SSC.

Please also refer to FIGS. 8A and 9. In one embodiment, when the capacitor mode signal SSC is enabled, the current mirror circuit 92 mirrors the current generated by the current source 91 to generate a current IC. The current IC charges the capacitor CLMT to generate a voltage VC. When VC rises to the threshold voltage Vth8 of the transistor M8, the transistor M8 is turned on to trigger the delayed signal SLMT to become enabled.

It should be noted that, in one embodiment, the delay time TD is determined according to the capacitance of the capacitor CLMT and the threshold voltage Vth8 of the transistor M8.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A power conversion circuit configured to convert a first power source to a second power source or convert the second power source to the first power source, comprising:
an N-level Pulse Width Modulation (PWM) power converter, configured to switch electrical connections of an inductor and at least one capacitor in an N-level PWM mode to perform conversion between the first power source and the second power source; and
a switched-capacitor power converter, configured to switch electrical connections of the at least one capacitor in a switched-capacitor conversion mode to perform conversion between the first power source and the second power source;
wherein the N-level PWM power converter includes:
a plurality of high-side switches serially coupled between the first power source and a switching node, wherein the plurality of high-side switches are sequentially coupled to at least one corresponding high-side intermediate node; and
a plurality of low-side switches serially coupled between the switching node and a ground potential, wherein the plurality of low-side switches are sequentially coupled to at least one corresponding low-side intermediate node;
wherein the plurality of high-side switches and the plurality of low-side switches are configured to periodically switch the electrical connections of the at least one capacitor in the N-level PWM mode, such that N-level voltages are generated at the switching node, enabling the inductor to perform conversion between the first power source and the second power source in an N-level pulse width modulation manner, where N is an integer equal to or greater than 3;
wherein the switched-capacitor power converter includes:
a plurality of shared switches, including a first portion of the plurality of high-side switches and a first portion of the plurality of low-side switches, wherein the shared switches are shared with the N-level PWM power converter; and
a plurality of auxiliary switches, wherein the shared switches and the auxiliary switches are configured to periodically switch the electrical connections of the at least one capacitor in the switched-capacitor conversion mode to perform switched-capacitor power conversion between the first power source and the second power source;
wherein in the switched-capacitor conversion mode, a second portion of the plurality of high-side switches and a second portion of the plurality of low-side switches are configured to remain non-conductive, such that a first terminal of the inductor is in a floating state;
wherein in the N-level PWM mode, the plurality of auxiliary switches are configured to remain non-conductive, such that the at least one capacitor is not directly connected to the second power source;
wherein during a mode transition between the N-level PWM mode and the switched-capacitor conversion mode, the power conversion circuit is configured to perform a soft-transition operation, in which, during a soft-transition period, when a first switch is in a conduction state while being periodically switched, a voltage at a control terminal of the first switch is controlled to a bias voltage to limit a first switch current flowing through the first switch;
wherein the first switch corresponds to one of the plurality of high-side switches, the plurality of low-side switches or the plurality of auxiliary switches.

2. The power conversion circuit of claim 1, wherein after the soft-transition period ends, when the first switch is in a conduction state while being periodically switched, a voltage at a control terminal of the first switch is controlled to a driving voltage,
wherein an absolute value of the driving voltage is greater than an absolute value of the bias voltage.

3. The power conversion circuit of claim 1, wherein the soft-transition period is positively correlated with a product of a capacitance of the at least one capacitor and an on-resistance of the first switch when conducting.

4. The power conversion circuit of claim 1, wherein during the soft-transition operation, when a voltage difference across the at least one capacitor falls within a target range, the soft-transition period is triggered to end,
wherein the target range is related to a second voltage of the second power source.

5. The power conversion circuit of claim 2, further comprising a control circuit configured to control the first switch, wherein the control circuit includes:
a driving circuit configured to generate a first control signal according to a PWM signal, wherein the first control signal is configured, during a switching period other than the soft-transition period, to control the control terminal of the first switch such that the first switch is periodically switched according to a duty cycle of the PWM signal, wherein an amplitude of the first control signal corresponds to the driving voltage; and
a current mirror circuit configured to generate a second control signal based on the PWM signal and a reference limit current, wherein the second control signal is configured, during the soft-transition period, to control the control terminal of the first switch so as to limit the first switch current, wherein an amplitude of the second control signal corresponds to the bias voltage;
wherein the first switch current is related to the reference limit current.

6. The power conversion circuit of claim 1, wherein in the N-level PWM mode, a ratio between a first voltage of the first power source and a second voltage of the second power source corresponds to a duty cycle associated with the N-level voltages;
and wherein in the switched-capacitor conversion mode, the ratio between the first voltage and the second voltage is M, and a first current of the first power source is constant, such that a second current of the second power source is constant and equal to M times the first current, where M is a real number greater than 1.

7. The power conversion circuit of claim 6, wherein the plurality of high-side switches include a first high-side switch and a second high-side switch serially coupled between the first power source and the switching node, and the first high-side switch and the second high-side switch are coupled to each other at a first high-side intermediate node;
wherein the plurality of low-side switches include a first low-side switch and a second low-side switch serially coupled between the ground potential and the switching node, and the first low-side switch and the second low-side switch are coupled to each other at a first low-side intermediate node;
wherein the first high-side switch and the first low-side switch correspond to the plurality of shared switches;
wherein the plurality of auxiliary switches include an upper auxiliary switch and a lower auxiliary switch, the upper auxiliary switch being coupled between the second power source and the first high-side intermediate node, and the lower auxiliary switch being coupled between the second power source and the first low-side intermediate node;
wherein the at least one capacitor includes a first capacitor, the first capacitor being coupled between the first high-side intermediate node and the first low-side intermediate node;
and wherein the first terminal of the inductor is coupled to the switching node, and a second terminal of the inductor is coupled to the second power source.

8. The power conversion circuit of claim 7, wherein N is equal to 3, wherein the N-level PWM mode corresponds to a 3-level PWM mode which includes:
a state A, in which the first high-side switch and the second low-side switch are conductive, and the second high-side switch and the first low-side switch are non-conductive, such that, in a steady state, a voltage at the switching node in the state A corresponds to one-half of the first voltage;
a state B, in which the first low-side switch and the second low-side switch are conductive, and the first high-side switch and the second high-side switch are non-conductive, such that the voltage at the switching node in the state B corresponds to the ground potential;
a state C, in which the second high-side switch and the first low-side switch are conductive, and the first high-side switch and the second low-side switch are non-conductive, such that, in a steady state, the voltage at the switching node in the state C corresponds to one-half of the first voltage; and
a state D, in which the first high-side switch and the second high-side switch are conductive, and the first low-side switch and the second low-side switch are non-conductive, such that the voltage at the switching node in the state D corresponds to the first voltage;
wherein in the 3-level PWM mode, the power conversion circuit periodically switches between combinations of the states A, B, C, and D within a switching cycle, such that the voltage at the switching node alternates between the first voltage and one-half of the first voltage, or alternates between one-half of the first voltage and the ground potential;
wherein in the 3-level PWM mode, the upper auxiliary switch and the lower auxiliary switch remain non-conductive, such that the first capacitor is not directly connected to the second power source.

9. The power conversion circuit of claim 7, wherein M is equal to 2, wherein the switched-capacitor conversion mode includes:
a state E, in which the first high-side switch and the lower auxiliary switch are conductive, and the upper auxiliary switch and the first low-side switch are non-conductive; and
a state F, in which the upper auxiliary switch and the first low-side switch are conductive, and the first high-side switch and the lower auxiliary switch are non-conductive;
wherein in the switched-capacitor conversion mode, the power conversion circuit is configured to periodically switch between the state E and the state F within a switching cycle, such that:
a first terminal of the first capacitor is periodically switched between the first voltage and the second voltage; and
a second terminal of the first capacitor is periodically switched between the second voltage and the ground potential correspondingly;
wherein in the switched-capacitor conversion mode, the second high-side switch and the second low-side switch remain non-conductive, such that a first terminal of the inductor is in a floating state.

10. A charging system, comprising: a power supplying unit configured to generate a direct current (DC) power source according to an input power source, wherein, in a switched-capacitor conversion mode, a direct current included in the direct current power source is constant; and
a charging circuit, connected to the power supplying unit with a detachable manner, configured to convert the DC power source into a charging power source to charge a battery, wherein the DC power source and the charging power source respectively correspond to one and the other of a first power source and a second power source, wherein the charging circuit includes:
an N-level Pulse Width Modulation (PWM) power converter, configured to switch electrical connections of an inductor and at least one capacitor in an N-level PWM mode to perform conversion between the first power source and the second power source; and
a switched-capacitor power converter, configured to switch electrical connections of the at least one capacitor in a switched-capacitor conversion mode to perform conversion between the first power source and the second power source;
wherein the N-level PWM power converter includes:
a plurality of high-side switches serially coupled between the first power source and a switching node, wherein the plurality of high-side switches are sequentially coupled to at least one corresponding high-side intermediate node; and
a plurality of low-side switches serially coupled between the switching node and a ground potential, wherein the plurality of low-side switches are sequentially coupled to at least one corresponding low-side intermediate node;
wherein the plurality of high-side switches and the plurality of low-side switches are configured to periodically switch the electrical connections of the at least one capacitor in the N-level PWM mode, such that N-level voltages are generated at the switching node, enabling the inductor to perform conversion between the first power source and the second power source in an N-level pulse width modulation manner, where N is an integer equal to or greater than 3;
wherein the switched-capacitor power converter includes:
a plurality of shared switches, including a first portion of the plurality of high-side switches and a first portion of the plurality of low-side switches, wherein the shared switches are shared with the N-level PWM power converter; and
a plurality of auxiliary switches, wherein the shared switches and the auxiliary switches are configured to periodically switch the electrical connections of the at least one capacitor in the switched-capacitor conversion mode to perform switched-capacitor power conversion between the first power source and the second power source;
wherein in the switched-capacitor conversion mode, a second portion of the plurality of high-side switches and a second portion of the plurality of low-side switches are configured to remain non-conductive, such that a first terminal of the inductor is in a floating state;
wherein in the N-level PWM mode, the plurality of auxiliary switches are configured to remain non-conductive, such that the at least one capacitor is not directly connected to the second power source;
wherein during a mode transition between the N-level PWM mode and the switched-capacitor conversion mode, the power conversion circuit is configured to perform a soft-transition operation, in which, during a soft-transition period, when a first switch is in a conduction state while being periodically switched, a voltage at a control terminal of the first switch is controlled to a bias voltage to limit a first switch current flowing through the first switch;
wherein the first switch corresponds to one of the plurality of high-side switches, the plurality of low-side switches or the plurality of auxiliary switches.

11. The charging system of claim 10, wherein after the soft-transition period ends, when the first switch is in a conduction state while being periodically switched, a voltage at a control terminal of the first switch is controlled to a driving voltage,
wherein an absolute value of the driving voltage is greater than an absolute value of the bias voltage.

12. The charging system of claim 10, wherein the soft-transition period is positively correlated with a product of a capacitance of the at least one capacitor and an on-resistance of the first switch when conducting.

13. The charging system of claim 10, wherein during the soft-transition operation, when a voltage difference across the at least one capacitor falls within a target range, the soft-transition period is triggered to end,
wherein the target range is related to a second voltage of the second power source.

14. The charging system of claim 11, further comprising a control circuit configured to control the first switch, wherein the control circuit includes:
a driving circuit configured to generate a first control signal according to a PWM signal, wherein the first control signal is configured, during a switching period other than the soft-transition period, to control the control terminal of the first switch such that the first switch is periodically switched according to a duty cycle of the PWM signal, wherein an amplitude of the first control signal corresponds to the driving voltage; and
a current mirror circuit configured to generate a second control signal based on the PWM signal and a reference limit current, wherein the second control signal is configured, during the soft-transition period, to control the control terminal of the first switch so as to limit the first switch current, wherein an amplitude of the second control signal corresponds to the bias voltage;
wherein the first switch current is related to the reference limit current.

15. The charging system of claim 10, wherein in the N-level PWM mode, a ratio between a first voltage of the first power source and a second voltage of the second power source corresponds to a duty cycle associated with the N-level voltages;
and wherein in the switched-capacitor conversion mode, the ratio between the first voltage and the second voltage is M, and a second current of the second power source is equal to M times a first current of the first power source, where M is a real number greater than 1.

16. The charging system of claim 15, wherein the plurality of high-side switches include a first high-side switch and a second high-side switch serially coupled between the first power source and the switching node, and the first high-side switch and the second high-side switch are coupled to each other at a first high-side intermediate node;
wherein the plurality of low-side switches include a first low-side switch and a second low-side switch serially coupled between the ground potential and the switching node, and the first low-side switch and the second low-side switch are coupled to each other at a first low-side intermediate node;
wherein the first high-side switch and the first low-side switch correspond to the plurality of shared switches;
wherein the plurality of auxiliary switches include an upper auxiliary switch and a lower auxiliary switch, the upper auxiliary switch being coupled between the second power source and the first high-side intermediate node, and the lower auxiliary switch being coupled between the second power source and the first low-side intermediate node;
wherein the at least one capacitor includes a first capacitor, the first capacitor being coupled between the first high-side intermediate node and the first low-side intermediate node;
and wherein the first terminal of the inductor is coupled to the switching node, and a second terminal of the inductor is coupled to the second power source.

17. The charging system of claim 16, wherein N equals 3, wherein the N-level PWM mode corresponds to a 3-level PWM mode which includes:
a state A, in which the first high-side switch and the second low-side switch are conductive, and the second high-side switch and the first low-side switch are non-conductive, such that, in a steady state, a voltage at the switching node in the state A corresponds to one-half of the first voltage;
a state B, in which the first low-side switch and the second low-side switch are conductive, and the first high-side switch and the second high-side switch are non-conductive, such that the voltage at the switching node in the state B corresponds to the ground potential;
a state C, in which the second high-side switch and the first low-side switch are conductive, and the first high-side switch and the second low-side switch are non-conductive, such that, in a steady state, the voltage at the switching node in the state C corresponds to one-half of the first voltage; and
a state D, in which the first high-side switch and the second high-side switch are conductive, and the first low-side switch and the second low-side switch are non-conductive, such that the voltage at the switching node in the state D corresponds to the first voltage;
wherein in the 3-level PWM mode, the charging circuit periodically switches between combinations of the states A, B, C, and D within a switching cycle, such that the voltage at the switching node alternates between the first voltage and one-half of the first voltage, or alternates between one-half of the first voltage and the ground potential;
wherein in the 3-level PWM mode, the upper auxiliary switch and the lower auxiliary switch remain non-conductive, such that the first capacitor is not directly connected to the second power source.

18. The charging system of claim 16, wherein M is equal to 2, wherein the switched-capacitor conversion mode includes:
a state E, in which the first high-side switch and the lower auxiliary switch are conductive, and the upper auxiliary switch and the first low-side switch are non-conductive; and
a state F, in which the upper auxiliary switch and the first low-side switch are conductive, and the first high-side switch and the lower auxiliary switch are non-conductive;
wherein in the switched-capacitor conversion mode, the charging circuit is configured to periodically switch between the state E and the state F within a switching cycle, such that:
a first terminal of the first capacitor is periodically switched between the first voltage and the second voltage; and
a second terminal of the first capacitor is periodically switched between the second voltage and the ground potential correspondingly;
wherein in the switched-capacitor conversion mode, the second high-side switch and the second low-side switch remain non-conductive, such that a first terminal of the inductor is in a floating state.

19. The charging system of claim 10, wherein the charging circuit switches between the N-level PWM mode and the switched-capacitor conversion mode based on a feedback signal,
wherein the feedback signal is related to a charging voltage or a charging current of the charging power;
wherein when a battery voltage of the battery is lower than a first predetermined voltage, the charging circuit operates in the N-level PWM mode to generate the charging current at a first level through pulse width modulation control based on the feedback signal to charge the battery;
wherein when the battery voltage is higher than the first predetermined voltage and lower than a second predetermined voltage, the charging circuit operates in the switched-capacitor conversion mode to generate the charging current at a second level to charge the battery, wherein the second level has a current multiplication ratio with respect to the direct current, wherein the first predetermined voltage is lower than the second predetermined voltage;
wherein when the battery voltage is higher than the second predetermined voltage, the charging circuit operates in the N-level PWM mode to generate the charging voltage at a predetermined level based on the feedback signal to charge the battery.
